(19) United States
(12) Patent Application Publication
(10) Pub. No.: US 2026/0107760 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Jaeyoung CHOI, Suwon-si (KR); Eunmi KIM, Suwon-si (KR); Pil-Kyu KANG, Suwon-si (KR); Jae-Wha PARK, Suwon-si (KR)

(73) Assignee: Samsung Electronics Co., Ltd., Suwon-si (KR)

(21) Appl. No.: 19/214,927

(22) Filed: May 21, 2025

(30) Foreign Application Priority Data
Oct. 14, 2024 (KR) 10-2024-0139733

(51) Int. Cl. H01L 23/532; H01L 23/00; H01L 23/528; H01L 25/16

(52) U.S. Cl. CPC H10W 20/4405; H10W 20/43; H10W 90/00; H10W 90/792

(57) ABSTRACT

A semiconductor package including a first semiconductor chip, where the first semiconductor chip may include a first semiconductor layer, an upper wire structure located on the first semiconductor layer, an upper connection pad located on the upper wire structure, and a first upper conductive pattern located between the upper wire structure and the upper connection pad, where the first upper conductive pattern may include aluminum doped with a metallic material having a lower coefficient of thermal expansion than aluminum.

### CROSS-REFERENCE TO RELATED APPLICATION

This application claims priority to and the benefit of Korean Patent Application No. 10-2024-0139733 filed in the Korean Intellectual Property Office on Oct. 14, 2024, the entire contents of which is incorporated herein by reference.

### BACKGROUND

### 1. Field

Inventive concepts relate to a semiconductor package.

### 2. Description of the Related Art

The semiconductor industry has sought to down-size, lighten, and make relatively thinner semiconductor packages for mounting in electronic devices, while simultaneously pursuing higher speed, multifunctionality, and relatively large capacity in response to the demand for down-sizing and lightening of electronic devices. Accordingly, desire for packaging technology that can store relatively more data and transmit data at a relatively faster rate is increasing, and as such packaging technology, for example related to a high bandwidth memory (HBM) capable of achieving a relatively high-level bandwidth by stacking a relatively large number of semiconductor chips on a substrate of the same surface area, has been developed.

In high bandwidth memory, a plurality of semiconductor chips may be stacked by, for example, performing a bonding process between semiconductor chips, and the stacked plurality of semiconductor chips may be disposed on a buffer die. However, as the semiconductor chips used in the high bandwidth memory may be relatively very thin, warpage may occur in the semiconductor chips due to, for example, the thermal stress and/or mechanical stress applied to the semiconductor chips.

### SUMMARY

Inventive concepts relate to a semiconductor package capable of, for example, improving reliability of (for example, related to) a junction (for example, bonding) process.

Technical solutions and/or advantages related to inventive concepts are not-limited the above-mentioned technical solutions and/or advantages. And, other unmentioned technical solutions and/or advantages can be clearly understood from the following description by those having ordinary skill in the technical field(s) to which inventive concepts pertain.

According to some example embodiments of inventive concepts, a semiconductor package may include a first semiconductor chip comprising a first semiconductor layer; an upper wire structure on the first semiconductor layer; an upper connection pad on the upper wire structure; and a first upper conductive pattern between the upper wire structure and the upper connection pad, wherein the first upper conductive pattern comprises aluminum doped with a metallic material, the metallic material having a lower coefficient of thermal expansion than aluminum.

According to some example embodiments of inventive concepts, a semiconductor package may include a first semiconductor chip comprising: a first semiconductor layer; an upper wire structure on the first semiconductor layer; an upper connection pad on the upper wire structure; and first upper conductive pattern and a second upper conductive pattern between the upper wire structure and the upper connection pad, wherein the first upper conductive pattern comprises aluminum that is not doped with silicon, and the second upper conductive pattern comprises aluminum doped with silicon.

According to some example embodiments of inventive concepts, a semiconductor package may include an interposer; a logic die on the interposer; and a high bandwidth memory on the interposer, wherein the high bandwidth memory comprises a first semiconductor chip and a second semiconductor chip, the second semiconductor chip connected to the first semiconductor chip, the first semiconductor chip comprises a first semiconductor layer; an upper wire structure on the first semiconductor layer; an upper connection pad on the upper wire structure; and a first upper conductive pattern between the upper wire structure and the upper connection pad, and the first upper conductive pattern comprises aluminum doped with a metallic material, the metallic material having a lower coefficient of thermal expansion than aluminum.

According to some example embodiments of inventive concepts, a method of manufacturing a semiconductor package may include forming an upper conductive pattern in in a first semiconductor chip, the upper conductive pattern being between a connection pad and an upper wire structure.

The method may further include bonding the first semiconductor chip to a second lower semiconductor chip.

The first and second semiconductor chips may be included in a high bandwidth memory.

The bonding of the first and second semiconductor chips may include hybrid bonding.

According to some example embodiments of inventive concepts, the first semiconductor chip may be bonded to the second semiconductor chip such that an upper surface of an upper connection pad of the first semiconductor chip is contact with a lower surface of a lower connection pad of the second semiconductor chip.

According to some example embodiments of inventive concepts, in the process of forming the upper conductive pattern located between the connection pad and the upper wire structure, an aluminum (Al) target that does not include silicon (Si) may be used such that the upper conductive pattern may not include silicon.

According to some example embodiments, the bonding the upper and lower semiconductor chips may be such that a grain size the upper conductive pattern may not increase due to heating of the bonding process such that warpage of the semiconductor chip due to the bonding process may be limited.

### BRIEF DESCRIPTION OF THE DRAWINGS

FIG. 1 is a cross-sectional view showing a semiconductor package according to some example embodiments.

FIG. 2 is an enlarged cross-sectional view of the region ‘A’ of FIG. 1.

FIG. 3 is a drawing for explaining the effect of a semiconductor package according to some example embodiments.

FIG. 4 is a cross-sectional view showing a semiconductor package according to some example embodiments.

FIG. 5 is a cross-sectional view showing a semiconductor package according to some example embodiments.

FIG. 6 is a cross-sectional view showing a semiconductor package according to some example embodiments.

FIG. 7 is a cross-sectional view showing a semiconductor package according to some example embodiments.

FIG. 8 is a cross-sectional view showing a semiconductor package according to some example embodiments.

FIG. 9 is a cross-sectional view showing a 2.5D semiconductor package including a bonding structure according to some example embodiments.

FIG. 10 is a cross-sectional view showing a 3D semiconductor package including a bonding structure according to some example embodiments.

### DETAILED DESCRIPTION

Inventive concepts will be described in detail hereinafter with reference to the accompanying drawings, in which various example embodiments of inventive concepts are shown. As those ordinarily skilled in the art would realize, the described example embodiments may be modified in various different ways, all without departing from the spirit or scope of inventive concepts.

The drawings and description are to be regarded as illustrative in nature and not restrictive. Like reference numerals designate like elements throughout the specification.

Size and thickness of each constituent element in the drawings may be arbitrarily illustrated for better understanding and ease of description, and the following example embodiments are not limited thereto. In the drawings, the thickness of layers, films, panels, regions, etc., may be exaggerated for clarity. In the drawings, the thickness of some layers and regions may be exaggerated for ease of description.

In addition, it will be understood that when an element such as a layer, film, region, or substrate is referred to as being “above” or “on” another element, it can be directly on the other element or intervening elements may also be present. In contrast, when an element is referred to as being “directly on” another element, there are no intervening elements present. Further, when an element is referred to as being “above” or “on” a reference element, it can be located above or below the reference element, and it is not necessarily referred to as being located “above” or “on” in a direction opposite to gravity (for example, not necessarily “on top of”.).

In addition, unless explicitly described to the contrary, the word “comprise”, and variations such as “comprises” or “comprising”, will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package according to example embodiments will be described with reference to drawings.

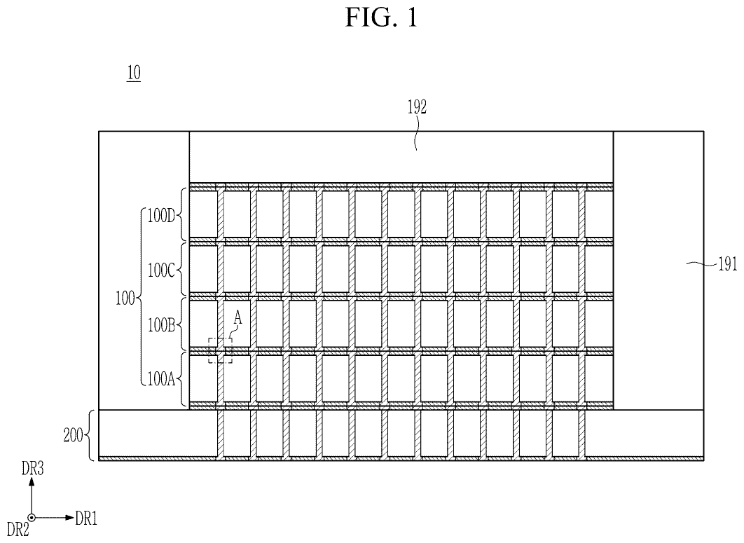

FIG. 1 is a drawing showing the semiconductor package according to some example embodiments.

Referring to FIG. 1, a semiconductor package 10 may include a semiconductor chip stacking structure 100, a lower die 200 located below the semiconductor chip stacking structure 100, a molding material 191 located on both sides of the semiconductor chip stacking structure 100, and a dummy silicon layer 192 located on the semiconductor chip stacking structure 100.

The semiconductor chip stacking structure 100 may have a structure in which a plurality of semiconductor chips 100A to 100D are stacked in one direction (e.g., a third direction DR3). The semiconductor chip stacking structure 100 may be disposed on the lower die 200. In some example embodiments, the lower die 200 may have a greater width in a first direction DR1, compared to the semiconductor chip stacking structure 100.

In some example embodiments, the semiconductor package 10 may include a high bandwidth memory (HBM). Each of the plurality of semiconductor chips 100A to 100D stacked in the semiconductor chip stacking structure 100 may be or include a memory chip (e.g., DRAM), and the lower die 200 may be or include a buffer die. In example embodiments described below, the semiconductor package 10 will be described to include a high bandwidth memory as an example, but example embodiments are not limited to the high bandwidth memory.

The lower die 200 may be located below the semiconductor chip stacking structure 100. As an example, the lower die 200 may be or include a logic chip. The logic chip may be or include, for example, at least one of a gate array, a cell base array, an embedded array, a structured application-specific integrated circuit (structured ASIC), a field-programmable gate array (FPGA), a complex programmable logic device (CPLD), a central processing unit (CPU), a microprocessor unit (MPU), a micro controller unit (MCU), a logic IC, an application processor (AP), a driver driving IC, an RF chip, and a CMOS image sensor. However, example embodiments are not limited thereto, and the lower die 200 may be or include a memory chip.

The semiconductor chip stacking structure 100 and the lower die 200 may be bonded by, for example, hybrid bonding. Each of the semiconductor chips 100A to 100D included in the semiconductor chip stacking structure 100 may be bonded to each other by, for example, hybrid bonding. The hybrid bonding may be performed by (for example, by utilizing) a bonding portion included in each of the semiconductor chips 100A to 100D and/or the lower die 200. The bonding portion may be a portion where the respective semiconductor chips are in contact with each other when the plurality of semiconductor chips 100A to 100D are stacked to be connected to each other. Alternatively, or additionally, the bonding portion may be a portion where the semiconductor chip and the lower die 200 are in contact with each other in a case that one of the plurality of semiconductor chips 100A to 100D and the lower die 200 are connected to each other.

Hybrid bonding may include, for example, bonding two or more devices by fusing the same materials of the two devices using bonding properties of the same material. For example, in a junction, metal-to-metal bonding and non-metal-to-non-metal bonding may mean that two devices are bonded to each other. According to hybrid bonding, it is possible to form I/Os with fine pitch. For example, when two semiconductor chips are bonded to each other, a bonding part of each semiconductor chip may include one or more connection pads and an insulating layer adjacent to the connection pad. For example, in the bonding part, the connection pads may be bonded to the connection pads, and the insulating layers may be bonded to the insulating layers.

The molding material 191 may be located on both sides of the semiconductor chip stacking structure 100. The molding material 191 may be located on the lower die 200. The molding material 191 may serve to protect and/or insulate the semiconductor chip stacking structure 100. In some example embodiments, the molding material 191 may be formed of a thermosetting resin such as, for example, epoxy resin. In some example embodiments, the molding material 191 may be an epoxy molding compound (EMC). In some example embodiments, the process of molding with the molding material 191 may include, for example, a compression molding or transfer molding process.

The dummy silicon layer 192 may be located on the semiconductor chip stacking structure 100. The dummy silicon layer 192 may be or include, for example, a configuration for dissipating heat generated in the high bandwidth memory to the outside. The dummy silicon layer 192 may include, for example, crystalline silicon. The thermal conductivity of silicon may have a greater value than the thermal conductivity of the molding material 191. The heat generated in the high bandwidth memory may be effectively dissipated by the dummy silicon layer 192 including silicon.

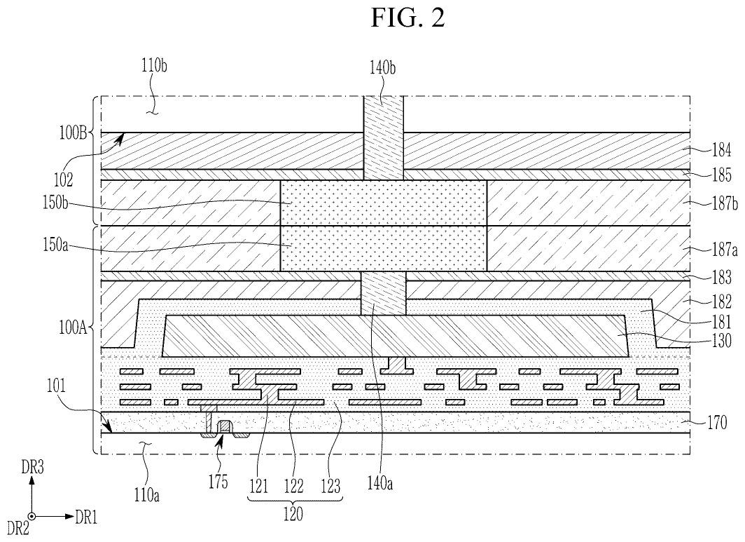

FIG. 2 is an enlarged cross-sectional view of the region ‘A’ of FIG. 1.

FIG. 2 may represent only a partial region of a partial region of the first semiconductor chip 100A and the second semiconductor chip 100B described with reference to FIG. 1. For example, a partial region of the first semiconductor chip 100A illustrated in FIG. 2 may be an upper region of the first semiconductor chip 100A. A partial region of the second semiconductor chip 100B illustrated in FIG. 2 may be a lower region of the second semiconductor chip 100B. For example, FIG. 2 may represent the bonding portion where an upper surface of the first semiconductor chip 100A and a lower surface of the second semiconductor chip 100B are bonded to each other.

Referring to FIG. 2, the semiconductor package according to some example embodiments may include the first semiconductor chip 100A and the second semiconductor chip 100B connected to the first semiconductor chip 100A.

The first semiconductor chip 100A may include a first semiconductor layer 110a, an interlayer insulating layer 170 located on the first semiconductor layer 110a, an upper wire structure 120 located on the interlayer insulating layer 170, an upper connection pad 150a located on the upper wire structure 120, and an upper conductive pattern 130 located between the upper wire structure 120 and the upper connection pad 150a.

The second semiconductor chip 100B may include a second semiconductor layer 110b, a lower connection pad 150b located below the second semiconductor layer 110b. Referring to FIG. 2, the first semiconductor chip 100A and the second semiconductor chip 100B may be connected to each other in a vertical direction.

The first semiconductor layer 110a may include, for example, a semiconductor element such as silicon (Si) or germanium (Ge), and/or a compound semiconductor such as silicon carbide (SiC), gallium arsenide (GaAs), indium arsenide (InAs), or indium phosphide (InP), but example embodiments are not limited thereto. The first semiconductor layer 110a may include a first surface 101 and a second surface (not shown in FIG. 2) facing the first surface 101. The first surface 101 may be a surface opposite to the second surface in the vertical direction. For example, the first surface 101 may be an upper surface of the first semiconductor layer 110a, and the second surface may be a lower surface of the first semiconductor layer 110a. The first surface 101 of the first semiconductor layer 110a may be formed as a plane parallel to the first direction DR1 and a second direction DR2 intersecting the first direction DR1.

Although not clearly shown in in FIG. 2, an upper region of the first semiconductor layer 110a may have, for example, a silicon-on-Insulator (SOI) structure. The first semiconductor layer 110a may include an active region, for example, an impurity-doped well, or an impurity-doped structure. The first semiconductor layer 110a may include various device isolation structures such as, for example, a shallow trench isolation (STI) structure. A plurality of individual devices 175 may be formed on the first surface 101 of the second semiconductor layer 110b. The individual device 175 illustrated in FIG. 2 is represented as a mere example, and various types of elements may be formed on the first surface 101. The plurality of individual devices 175 may include, for example, one or more of each of a transistor, and/or a memory cell. The memory cell may include, for example, dynamic random-access memory (DRAM) cell, static random-access memory (SRAM) cell, flash memory cell, magnetoresistive random access memory (MRAM) cell, phase-change random access memory (PRAM) cell, ferroelectric random access memory (FeRAM) cell, resistive random-access memory (RRAM) cell, or a combination thereof. In some example embodiments, the plurality of individual devices 175 may include passive elements such as, for example, capacitors and resistors, but example embodiments are not limited thereto.

The interlayer insulating layer 170 may cover or at least partially cover the first surface 101 of the first semiconductor layer 110a. The interlayer insulating layer 170 may cover the plurality of individual devices 175 formed on the first surface 101. The interlayer insulating layer 170 may include an insulating material. The interlayer insulating layer 170 may include, for example, silicon oxide (SiO₂), silicon nitride (SiN_{X}), silicon oxynitride (SiON), or a combination thereof, but example embodiments are not limited thereto. The plurality of individual devices 175 may be connected to wires included the upper wire structure 120 to be described later. The interlayer insulating layer 170 may include a plurality of electrodes and/or vias for connecting the plurality of individual devices 175 to wires included the upper wire structure 120.

The upper wire structure 120 may be located on the interlayer insulating layer 170. Referring to FIG. 2, the upper wire structure 120 may include an upper wire layers 122, an upper wire vias 121 and an upper wire insulation layer 123 surrounding the upper wire layers 122 and upper wire vias 121.

Referring to FIG. 2, at least two or more upper wire layers 122 may be located apart from each other in the third direction DR3, within the upper wire insulation layer 123. The upper wire via 121 may be located between two upper wire layers 122 located in different layers. The upper wire via 121 may have an upper surface in contact with one lower surface among the two upper wire layers 122 located in different layers. The upper wire via 121 may have a lower surface in contact with one upper surface among the two upper wire layers 122 located in different layers. The upper wire via 121 may electrically connect the two upper wire layers 122 located in different layers. In some example embodiments, among the upper wire vias 121, an upper surface of at least one among the upper wire vias 121 located uppermost (for an example at an uppermost level) may be connected to a lower surface of the upper conductive pattern 130 to be described later. However, example embodiments are not limited thereto, and unlike what is shown in FIG. 2, among the upper wire layers 122, an upper surface of at least one or more among the upper wire layers 122 located uppermost may be connected to the lower surface of the upper conductive pattern 130 to be described later.

In some example embodiments, the upper wire layers 122 and the upper wire vias 121 may include a conductive material. For example, the upper wire layers 122 and the upper wire vias 121 may include at least one of a metal, a metal alloy, a conductive metal nitride, a conductive metal carbide, a conductive metal oxide, a conductive metal carbonitride, and a two-dimensional (2D) material, respectively. The metal may include, for example, at least one of titanium (Ti), tantalum (Ta), tungsten (W), nickel (Ni), cobalt (Co), platinum (Pt), copper (Cu) and aluminum (Al), but example embodiments are not limited thereto.

The upper wire insulation layer 123 may be disposed between and/or around the upper wire layers 122 and the upper wire vias 121 to insulate them. The upper wire insulation layer 123 may surround or at least partially surround the upper wire layers 122 and the upper wire vias 121. The upper wire layers 122 and the upper wire vias 121 may be located inside the upper wire insulation layer 123. The upper wire insulation layer 123 may include an insulating material. The upper wire insulation layer 123 may include, for example, at least one of silicon oxide (SiO₂), silicon nitride (SiN_{X}), silicon nitride oxide (SiON), or a combination thereof, but example embodiments are not limited thereto.

The upper conductive pattern 130 may be located on an upper surface of the upper wire structure 120. The upper conductive pattern 130 may be in contact with the upper surface of the upper wire structure 120. The upper conductive pattern 130 may have (for example, define or at least partially define) an upper surface of the upper wire vias 121, and a lower surface in contact with an upper surface and/or region of the upper wire insulation layer 123, but example embodiments are not limited thereto. The upper conductive pattern 130 may be connected to the upper connection pad 150a to be described later.

The upper conductive pattern 130 may have a plate shape having a flat upper surface. Referring to FIG. 2, the upper conductive pattern 130 may have a trapezoidal shape, in a cross-sectional view. For example, a width of the upper conductive pattern 130 along the first direction DR1 may gradually increase as it becomes closer (for example, in, or when moving in, a direction towards) to the upper surface of the upper wire structure 120, which in some example embodiments may be defined to be coplanar and/or contiguous with a lower surface of the conductive pattern 130. However, example embodiments are not limited thereto, and the width of the upper conductive pattern 130 along the first direction DR1 may be constant regardless of a distance to the upper surface of the upper wire structure 120. In some example embodiments, a thickness of the upper conductive pattern 130 may be relatively thick, compared to a thickness of the upper wire vias 121 and the upper wire layers 122. As an example, the thickness of the upper conductive pattern 130 may be about twice to about 100 times of a thickness of the upper wire layer 122, but example embodiments are not limited thereto. For example, the thickness of the upper conductive pattern 130 may be greater than or equal to about 0.5 μm and smaller than or equal to 2.5 μm, but example embodiments are not limited thereto.

In some example embodiments, by forming the thickness of the upper conductive pattern 130 to be sufficiently thick, an upper surface of the upper conductive pattern 130 and upper surfaces of the insulation layers 181, 182, and 183 covering it may be formed flat, and accordingly, the upper connection pad 150a to be described later may be stably deposited on an insulation layer 183.

In some example embodiments, by forming the upper conductive pattern 130 having a thicker thickness compared to the upper wire layer 122 between the upper wire structure 120 and the upper connection pad 150a, the electric characteristic of the individual devices formed on the first surface 101 may be improved, and the reliability may be improved.

The upper conductive pattern 130 may include a conductive material. For example, the upper conductive pattern 130 may include at least one of a metal, a metal alloy, a conductive metal nitride, a conductive metal carbide, a conductive metal oxide, a conductive metal carbonitride, and a two-dimensional (2D) material, but example embodiments are not limited thereto. The metal may include, for example, at least one of titanium (Ti), tantalum (Ta), tungsten (W), nickel (Ni), cobalt (Co), platinum (Pt), copper (Cu) and aluminum (Al), but example embodiments are not limited thereto.

In some example embodiments, the upper conductive pattern 130 may include aluminum (Al). In some example embodiments, the upper conductive pattern 130 may not include silicon (Si). This may be related to process characteristics of using a metal target that is not doped with silicon (Si) in the process of forming the upper conductive pattern 130, during the manufacturing process of the semiconductor package according to some example embodiments. For example, in some example embodiments, the upper conductive pattern 130 may be performed by using a physical vapor deposition (PVD) process, for example, a sputtering process. For example, the target used in the sputtering process may include a metal that is not doped with silicon (Si). For example, the target used in the sputtering process may include aluminum (Al) that is not doped with silicon (Si). Accordingly, the upper conductive pattern 130 according to some example embodiments may include aluminum (Al), but may not include silicon (Si).

According to some example embodiments, in a case of using aluminum (Al) that is not doped with silicon (Si) target, the size of grains of the aluminum (Al) included in the upper conductive pattern 130 may be initially relatively greater, and, for example, warpage of the semiconductor chip in the bonding process may be reduced or minimized. The specific details of this will be described later.

In some example embodiments, the aluminum (Al) included in the upper conductive pattern 130 may be doped with a metallic material having a comparatively low coefficient of thermal expansion (CTE). For example, the aluminum (Al) included in the upper conductive pattern 130 may be doped with the metallic material having a lower coefficient of thermal expansion than aluminum (Al). The metallic material having a lower coefficient of thermal expansion than aluminum (Al) may include, for example, at least one of copper (Cu), ruthenium (Ru), tungsten (W), and nickel (Ni).

According to some example embodiments, as the upper conductive pattern 130 is doped with the metallic material having a smaller coefficient of thermal expansion than aluminum (Al), the degree to which the upper conductive pattern 130 expands in a bonding process in which a heat treatment of a comparatively high temperature is applied may be reduced. For example, in the bonding process, the degree of warpage of the semiconductor chips 100A and 100B bonded to each other may be limited, reduced, or minimized, accordingly improving the reliability of the bonding process.

The semiconductor package according to some example embodiments may further include the insulation layers 181, 182, and 183 located on the upper conductive pattern 130.

A first insulation layer 181 may be located on the upper wire structure 120 and the upper conductive pattern 130. The first insulation layer 181 may cover at least a partial region of an upper surface and of a side surface of the upper conductive pattern 130. At least a partial region of the first insulation layer 181 may be penetrated by a first through via 140a to be described later.

The first insulation layer 181 may include an insulating material. For example, the first insulation layer 181 may include the same insulating material as the upper wire insulation layer 123, and in for example, a boundary between the first insulation layer 181 and the upper wire insulation layer 123 may not be visible. However, example embodiments are not limited thereto, the first insulation layer 181 may include a different insulating material from the upper wire insulation layer 123.

A second insulation layer 182 may be located on the first insulation layer 181. The second insulation layer 182 may cover or at least partially cover an upper surface and a side surface of the first insulation layer 181. At least a partial region of the first insulation layer 181 may be penetrated by the first through via 140a to be described later.

A third insulation layer 183 may be located on the second insulation layer 182. At least a partial region of the third insulation layer 183 may be penetrated by the first through via 140a to be described later. An upper surface of the third insulation layer 183 may be in contact with a lower surface of the upper connection pad 150a, through a partial region.

In some example embodiments, each of the insulation layers 181, 182, and 183 may include an insulating material. For example, the insulation layers 181, 182, and 183 may include at least one of silicon oxide (SiO₂), silicon nitride (SiNₓ), and silicon oxynitride (SiON).

In some example embodiments, the insulation layers 181, 182, and 183 may include the same insulating material, and for example, the boundary between the insulation layers 181, 182, and 183 may not be visible. In some example embodiments, at least one of the insulation layers 181, 182, and 183 may include a different insulating material from other insulation layers 181, 182, and 183. For example, the first insulation layer 181 and the second insulation layer 182 may include silicon oxide (SiO₂), and the third insulation layer 183 may include silicon nitride (SiN_{X}). The first insulation layer 181 and the third insulation layer 183 may include, for example, an oxide layer formed by using high density plasma (HDP) and/or tetraethyl orthosilicate (TEOS), but example embodiments are not limited thereto.

The semiconductor package according to some example embodiments may include the first through via 140a penetrating at least a partial region of any or each of the insulation layers 181, 182, and 183. The first through via 140a may be located between the upper conductive pattern 130 and the upper connection pad 150a to be described later, and may electrically connect the upper conductive pattern 130 and the upper connection pad 150a. The lower surface of the upper conductive pattern 130 may be in contact with at least a partial region of the upper conductive pattern 130, and upper surface may be in contact with at least a partial region of the upper connection pad 150a.

The upper connection pad 150a may be located on the upper conductive pattern 130. The upper connection pad 150a may be connected to the lower connection pad 150b to be described later, at a bonding portion of the first semiconductor chip 100A and the second semiconductor chip 100B. The upper connection pad 150a may electrically connect the first semiconductor chip 100A and the second semiconductor chip 100B. Referring to FIG. 2, the upper connection pad 150a may be located on the third insulation layer 183.

The upper connection pad 150a may be connected to the upper conductive pattern 130 by the first through via 140a. The upper connection pad 150a may be electrically connected to the lower connection pad 150b to be described later. An upper surface of the upper connection pad 150a may be in contact with a lower surface of the lower connection pad 150b through at least a partial region.

The upper connection pad 150a may include a conductive material. The upper connection pad 150a may include, for example, at least one of a metal, a metal alloy, a conductive metal nitride, a conductive metal carbide, conductive metal oxide, but example embodiments are not limited thereto. For example, the upper connection pad 150a may include copper (Cu).

The semiconductor package according to some example embodiments may further include an upper interface insulation layer 187a located on the upper wire structure 120. Referring to FIG. 2, the upper interface insulation layer 187a may be located on the upper surface of the third insulation layer 183, and may surround or at least partially surround a side surface of the upper connection pad 150a. An upper surface of the upper interface insulation layer 187a may be in contact with a lower surface of a lower interface insulation layer 187b to be described later through at least a partial region.

The upper interface insulation layer 187a may include an insulating material. For example, the upper interface insulation layer 187a may include at least one of silicon oxide (SiO₂), silicon nitride (SiNₓ), and silicon oxynitride (SiON), but example embodiments are not limited thereto. In some example embodiments, the upper interface insulation layer 187a may include a same insulating material as the lower interface insulation layer 187b to be described later.

The second semiconductor layer 110b may include a semiconductor material. The second semiconductor layer 110b may include a semiconductor material that is the same as or different from that of the first semiconductor layer 110a. A detailed description thereof will be omitted. The second semiconductor layer 110b may include a first surface (not shown in FIG. 2) and a second surface 102 facing the first surface. The first surface may be a surface opposite to the second surface 102 in the vertical direction. For example, the first surface may be an upper surface of the second semiconductor layer 110b, and the second surface 102 may be a lower surface of the second semiconductor layer 110b. The second surface 102 of the second semiconductor layer 110b may be formed as a plane parallel to the first direction DR1 and the second direction DR2.

The semiconductor package according to some example embodiments may further include the insulation layers 184 and 185 located on the lower surface of the second semiconductor layer 110b. A fourth insulation layer 184 may be located on the lower surface of the second semiconductor layer 110b. A fifth insulation layer 185 may be located on a lower surface of the fourth insulation layer 184. At least a partial region of the fourth insulation layer 184 and the fifth insulation layer 185 may be penetrated by a second through via 140b to be described later. At least a partial region of a lower surface of the fifth insulation layer 185 may be in contact with an upper surface of the lower connection pad 150b.

The fourth insulation layer 184 and the fifth insulation layer 185 may include an insulating material. In some example embodiments, the insulation layers 184 and 185 may include at least one of silicon oxide (SiO₂), silicon nitride (SiNₓ), and silicon oxynitride (SiON), but example embodiments are not limited thereto.

In some example embodiments, the insulation layers 184 and 185 may include the same insulating material, and in this case, the boundary between the insulation layers 184 and 185 may not be visible. In some example embodiments, the insulation layers 184 and 185 may include different insulating materials. For example, the fourth insulation layer 184 may include silicon oxide (SiO₂), and the fifth insulation layer 185 may include silicon nitride (SiN_{X}). The fourth insulation layer 184 may include, for example, an oxide layer formed by using high density plasma (HDP) and/or tetraethyl orthosilicate (TEOS), but example embodiments are not limited thereto.

The second through via 140b may penetrate the second semiconductor layer 110b in the third direction DR3. The third direction DR3 may be a direction perpendicular to the first direction DR1 and the second direction DR2. At least a portion of side wall of the second through via 140b may be surrounded or at least partially surrounded by the second semiconductor layer 110b. The second through via 140b may penetrate at least a partial region of the fourth insulation layer 184 and the fifth insulation layer 185.

The second through via 140b may be formed by, for example, a method of forming a hole vertically penetrating the second semiconductor chip 100B and filling or at least partially filling the hole with a conductive material to be connected to an electrode. For example, the hole penetrating the second semiconductor chip 100B may be formed by deep etching, but example embodiments are not limited thereto. In some example embodiments, the hole(s) penetrating the second semiconductor chip 100B may be formed by a laser. In some example embodiments, the hole(s) may be filled with a conductive material by electrolytic plating. In some example embodiments, the second through via 140b may include at least one of tungsten (W), aluminum (Al), copper (Cu) and an alloy thereof, but example embodiments are not limited thereto.

The lower connection pad 150b may be located below the second semiconductor layer 110b. Referring to FIG. 2, the lower connection pad 150b may be located on the lower surface of the fifth insulation layer 185. The lower connection pad 150b may be connected to the upper connection pad 150a, at the bonding portion of the first semiconductor chip 100A and the second semiconductor chip 100B. The lower connection pad 150b may electrically connect the first semiconductor chip 100A and the second semiconductor chip 100B.

The lower connection pad 150b may be electrically connected to the upper connection pad 150a. The lower surface of the lower connection pad 150b may be in contact with the upper surface of the upper connection pad 150a through at least a partial region.

The lower connection pad 150b may include a conductive material. The lower connection pad 150b may include at least one of a metal, a metal alloy, a conductive metal nitride, a conductive metal carbide, conductive metal oxide. For example, the lower connection pad 150b may include copper (Cu).

The semiconductor package according to some example embodiments may further include the lower interface insulation layer 187b located below the second semiconductor layer 110b. Referring to FIG. 2, the lower interface insulation layer 187b may be located on the lower surface of the fifth insulation layer 185, and may surround a side surface of the lower connection pad 150b. The lower surface of the lower interface insulation layer 187b may be in contact with the upper surface of the upper interface insulation layer 187a through at least a partial region.

The lower interface insulation layer 187b may include an insulating material. For example, the upper interface insulation layer 187a may include at least one of silicon oxide (SiO₂), silicon nitride (SiNₓ), and silicon oxynitride (SiON). In some example embodiments, the lower interface insulation layer 187b may include the same insulating material as the lower interface insulation layer 187b, but example embodiments are not limited thereto.

In some example embodiments, the first semiconductor chip 100A and the second semiconductor chip 100B may be bonded by, for example, hybrid bonding. When the first semiconductor chip 100A and the second semiconductor chip 100B are bonded, as shown in FIG. 2, the upper surface of the first semiconductor chip 100A of the upper connection pad 150a may be in contact with a lower surface of a lower portion connection pad 150b of the second semiconductor chip 100B, and the upper surface of the first semiconductor chip 100A of the upper interface insulation layer 187a may be in contact with the lower surface of the lower interface insulation layer 187b of the second semiconductor chip 100B.

After the first semiconductor chip 100A and the second semiconductor chip 100B are bonded, the vicinity of the bonding portion of the semiconductor package according to some example embodiments may be or become heated to a predetermined, or alternatively, desired, temperature. For example, the semiconductor package may be heated to about 180° C. to about 250° C., but example embodiments are not limited thereto. Accordingly, the volume of the upper conductive pattern 130 may increase, and warpage of the semiconductor chips 100A and 100B may occur. In a case of the semiconductor package according to some example embodiments, the upper conductive pattern 130 may be formed by using aluminum (Al) that is not doped with silicon (Si) target, and for example, warpage of the semiconductor chips 100A and 100B in the bonding process may be limited, reduced, or minimized.

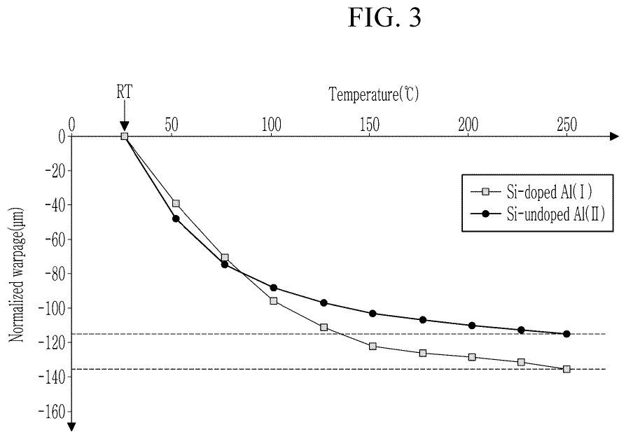

FIG. 3 is a drawing illustrating the effect of the semiconductor package according to some example embodiments.

In more detail, FIG. 3 is a graph illustrating the warpage skew of the semiconductor package according to the temperature, in the process of forming the upper conductive pattern 130, with respect to the case (I) of using the aluminum (Al) target doped with silicon (Si) and the case (II) of using the aluminum (Al) target that is not doped with silicon (Si). The warpage skew may mean a difference in warpage of the semiconductor chip at a room temperature RT and a high temperature. FIG. 3 shows a graph obtained by measuring the warpage of the semiconductor chip in the case (I) and the case (II), while increasing the temperature from the room temperature to 250° C.

Referring to FIG. 3, around 180° C. to 250° C., which may be the heat treatment temperature in a bonding process of the semiconductor package according to some example embodiments, the warpage skew may be greater in the case (I) of using the aluminum (Al) target doped with silicon (Si) than in the case (II) of using the aluminum (Al) target that is not doped with silicon (Si).

For example, in the process of forming the upper conductive pattern 130, the case (I) of using the aluminum (Al) target doped with silicon (Si), silicon (Si) may serve as an impurity with respect to aluminum (Al), and accordingly, the aluminum (Al) included in the upper conductive pattern 130 may be formed with a relatively small size of grains. Thereafter, in the heat treatment process of the bonding process, the size of grain may increase as adjacent grains are bonded, and during this process, entire volume of the upper conductive pattern 130 may increase significantly.

Alternatively, in the process of forming the upper conductive pattern 130, the case (II) of using the aluminum (Al) target that is not doped with silicon (Si), aluminum (Al) may be formed with a greater size of grains, compared to the case (I). Initially, aluminum (Al) may be formed with a sufficiently great size of grains, such that the size of grains may not become greater at a higher temperature. Accordingly, thereafter, in the heat treatment process of the bonding process, the degree to which the entire volume of the upper conductive pattern 130 increases may be smaller compared to the case (I), and accordingly, the warpage skew of the semiconductor chip in the bonding process may be smaller compared to the case (I).

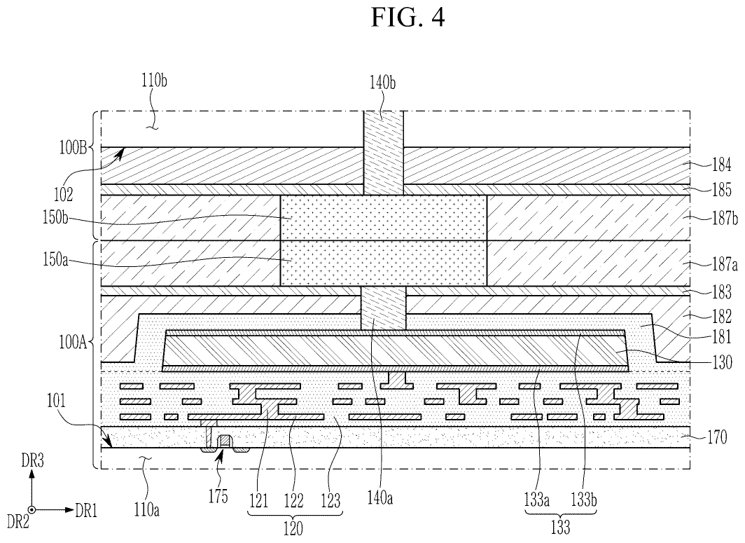

FIG. 4 is a cross-sectional view showing the semiconductor package according to some example embodiments.

Since the semiconductor package illustrated in FIG. 4 is largely the same as the semiconductor package described above, some description thereof will be omitted, and the differences will be mainly described below. The semiconductor package according to some example embodiments may be different from the above example embodiments in that it further includes a barrier pattern 133.

Referring to FIG. 4, a first barrier pattern 133a may be located on the lower surface of the upper conductive pattern 130, and a second barrier pattern 133b may be located on the upper surface of the upper conductive pattern 130. The first barrier pattern 133a may be in contact with the lower surface of the upper conductive pattern 130, and the second barrier pattern 133b may be in contact with the upper surface of the upper conductive pattern 130. In some example embodiments, the barrier pattern 133 may have a thinner thickness along the third direction DR3, compared to the upper conductive pattern 130. For example, a thickness of the first barrier pattern 133a may be about 100 nm, but example embodiments are not limited thereto. For example, a thickness of the second barrier pattern 133b may be about 800 nm, but example embodiments are not limited thereto.

In some example embodiments, the barrier pattern 133 may include a metallic material. For example, the first barrier pattern 133a may include titanium (Ti), and the second barrier pattern 133b may include titanium nitride (TiN), but example embodiments are not limited thereto.

When the barrier pattern 133 is not included, for example, the aluminum (Al) included in the upper conductive pattern 130 may infiltrate into another layer outside the upper conductive pattern 130, for example during or in relation to the heat treatment process of the bonding process, which may affect the size of grains of the upper conductive pattern 130.

In some example embodiments, the barrier pattern 133 may limit, reduce, or prevent the metallic material included in the upper conductive pattern 130 from infiltrating into another layer outside the upper conductive pattern 130, for example during the manufacturing process of the semiconductor package, and accordingly, may limit, reduce, or prevent occurrence and/or magnitude of warpage in the semiconductor chips 100A and 100B, for example during or related to the bonding process.

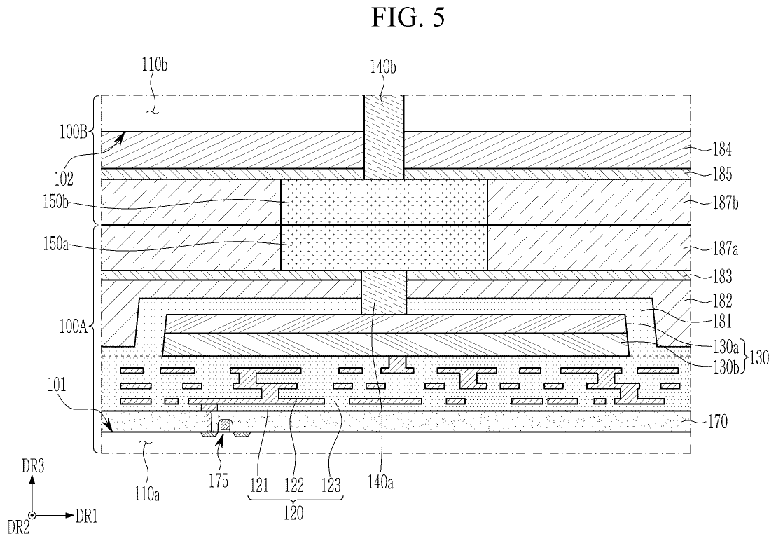

FIG. 5 is a cross-sectional view showing the semiconductor package according to some example embodiments.

Since the semiconductor package illustrated in FIG. 5 is largely the same as the semiconductor package described above, some description thereof will be omitted, and the differences will be mainly described below. The semiconductor package according to some example embodiments may be different from the above example embodiments in that the upper conductive pattern 130 includes a first upper conductive pattern 130a and a second upper conductive pattern 130b.

Referring to FIG. 5, the upper conductive pattern 130 may include the first upper conductive pattern 130a and the second upper conductive pattern 130b stacked along the third direction DR3. In some example embodiments, the first upper conductive pattern 130a may include aluminum (Al) that is not doped with silicon (Si), and the second upper conductive pattern 130b may include aluminum (Al) doped with silicon (Si). In some example embodiments, the aluminum (Al) included in the second upper conductive pattern 130b may have a smaller size of grains, compared to the aluminum (Al) included in the first upper conductive pattern 130a. The second upper conductive pattern 130b may be located below the first upper conductive pattern 130a. For example, referring to FIG. 5, the second upper conductive pattern 130b may be located between the first upper conductive pattern 130a and the upper wire structure 120. However, example embodiments are not limited thereto, the second upper conductive pattern 130b may be located above the first upper conductive pattern 130a. For example, the second upper conductive pattern 130b may be located between the first upper conductive pattern 130a and the upper connection pad 150a.

The aluminum (Al) that is not doped with silicon (Si) may have a lesser hardness, compared to aluminum (Al) doped with silicon (Si). In some example embodiments, the upper conductive pattern 130 may include both of aluminum (Al) that is not doped with silicon (Si) and aluminum (Al) doped with silicon (Si). According to some example embodiments, the upper conductive pattern 130 may have a higher hardness, compare to the semiconductor package described with reference to FIG. 2. According to some example embodiments, the upper conductive pattern 130 may have a lesser warpage in the bonding process, compared to a case of including only aluminum (Al) doped with silicon (Si).

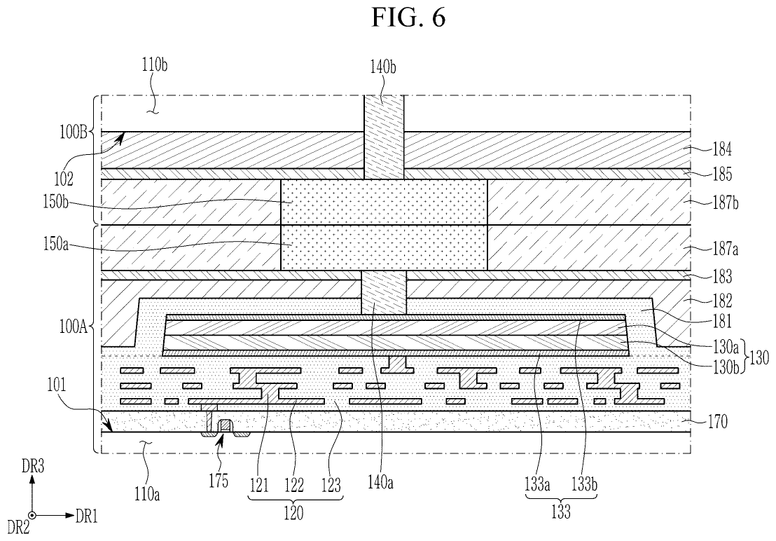

FIG. 6 is a cross-sectional view showing the semiconductor package according to some example embodiments.

Since the semiconductor package illustrated in FIG. 6 is largely the same as the semiconductor package described above, some description thereof will be omitted, and the differences will be mainly described below. The semiconductor package according to some example embodiments may be different from the above example embodiments in that that it includes the barrier pattern 133 and the upper conductive pattern 130 includes the first upper conductive pattern 130a and the second upper conductive pattern 130b.

Referring to FIG. 6, the upper conductive pattern 130 may include the first upper conductive pattern 130a and the second upper conductive pattern 130b stacked along the third direction DR3. The second barrier pattern 133b may be located on the first barrier pattern 133a may be located on the lower surface of the upper conductive pattern 130, and an upper conductive pattern 130 upper surface.

The first upper conductive pattern 130a may include aluminum (Al) that is not doped with silicon (Si), and the second upper conductive pattern 130b may include aluminum (Al) doped with silicon (Si). In some example embodiments, the first barrier pattern 133a may include titanium (Ti), and the second barrier pattern 133b may include titanium nitride (TiN). The configurations and effects of the semiconductor package according to some example embodiments may be the same as or similar to that described with reference to FIG. 4 and FIG. 5 taken together, and a detailed description thereof will be omitted.

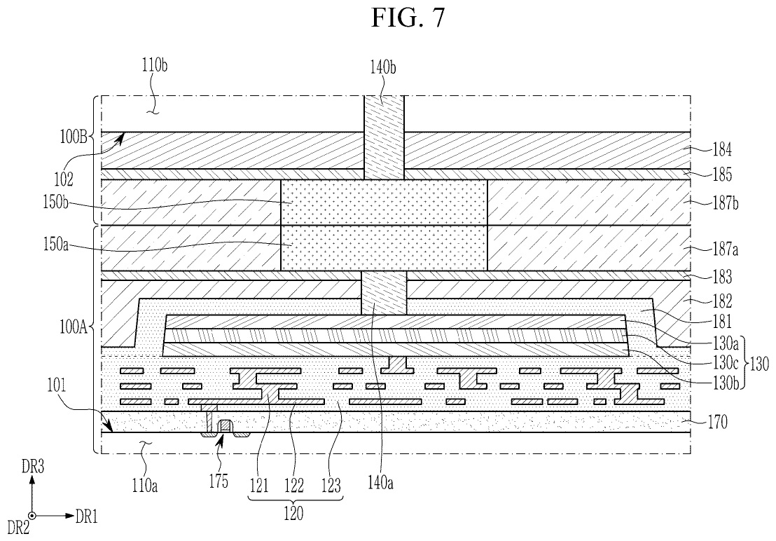

FIG. 7 is a cross-sectional view showing the semiconductor package according to some example embodiments.

Since the semiconductor package illustrated in FIG. 7 is largely the same as the semiconductor package described above, some description thereof will be omitted, and the differences will be mainly described below. The semiconductor package according to some example embodiments may be different from the above example embodiments in that the upper conductive pattern 130 includes the first upper conductive pattern 130a, the second upper conductive pattern 130b, and a third upper conductive pattern 130c.

The upper conductive pattern 130 may include the first upper conductive pattern 130a, the second upper conductive pattern 130b and the third upper conductive pattern 130c stacked along the third direction DR3.

Referring to FIG. 7, the first upper conductive pattern 130a may be located on the second upper conductive pattern 130b. The third upper conductive pattern 130c may be located between the first upper conductive pattern 130a and the second upper conductive pattern 130b.

In some example embodiments, the first upper conductive pattern 130a may include aluminum (Al) doped with the metallic material having a lower coefficient of thermal expansion than aluminum (Al). The metallic material having a lower coefficient of thermal expansion than aluminum (Al) may include, for example, at least one of copper (Cu), ruthenium (Ru), tungsten (W), or nickel (Ni), but example embodiments are not limited thereto.

In some example embodiments, the second upper conductive pattern 130b may include aluminum (Al) doped with silicon (Si), and the third upper conductive pattern 130c may include aluminum (Al) that is not doped with silicon (Si).

According to some example embodiments, as the upper conductive pattern 130 is doped with the metallic material having a smaller coefficient of thermal expansion than aluminum (Al), the degree to which the upper conductive pattern 130 expands in the bonding process in which a heat treatment of a comparatively high temperature is applied may be reduced. For example, in the bonding process, the degree of warpage of the semiconductor chips 100A and 100B bonded to each other may be limited, reduced, or minimized, accordingly improving the reliability of the bonding process.

Unlike what is shown in FIG. 7, the semiconductor package according to some example embodiments may further include the barrier pattern 133 described with reference to FIG. 4. For example the first barrier pattern 133a (see FIG. 4) including titanium (Ti) may be located on a lower surface of the second upper conductive pattern 130b, and the second barrier pattern 133b (see FIG. 4) including titanium nitride (TiN) may be located on an upper surface of the first upper conductive pattern 130a.

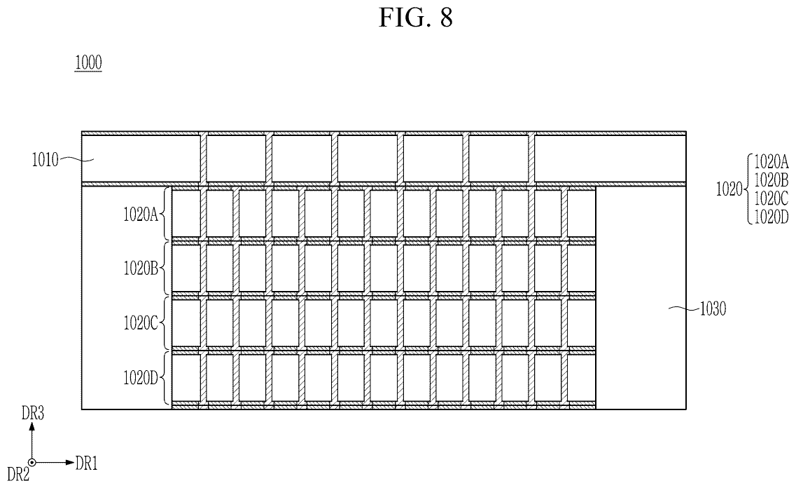

FIG. 8 is a drawing showing the semiconductor package of some example embodiments.

Referring to FIG. 8, a semiconductor package 1000 may include a semiconductor chip stacking structure 1020, a top die 1010, and a molding material 1030.

The semiconductor chip stacking structure 1020 may have a structure in which a plurality of semiconductor chips 1020A to 1020D are stacked in one direction (e.g., the second direction DR2). The top die 1010 may be disposed on the semiconductor chip stacking structure 1020. In some example embodiments, the top die 1010 may have a greater width in the first direction DR1, compared to the semiconductor chip stacking structure 1020.

Each of the plurality of semiconductor chips 1020A to 1020D stacked in the semiconductor chip stacking structure 1020 may, for example, be or include a memory chip. The top die 1010 may, for example, be or include a buffer die, or logic die. For example, the top die 1010 may be or include one or more of a central processing unit (CPU) chip, a graphics processing unit (GPU) chip, or an application processor (AP) chip.

The semiconductor chip stacking structure 1020 and the top die 1010 may be bonded by, for example, hybrid bonding. Each of the semiconductor chips 1020A to 1020D included in the semiconductor chip stacking structure 1020 may be, for example, bonded to each other by hybrid bonding. The hybrid bonding may be performed by a bonding portion included in each of the semiconductor chips 1020A to 1020D or the top die 1010. The bonding portion may be a portion where the respective semiconductor chips are in contact with each other when a plurality of semiconductor chips 100A to 100E are stacked to be connected to each other. Alternatively, or additionally, the bonding portion may be a portion where the semiconductor chip and the top die 1010 are in contact with each other when one of the plurality of semiconductor chips 1020A to 1020D and the top die 1010 are connected to each other.

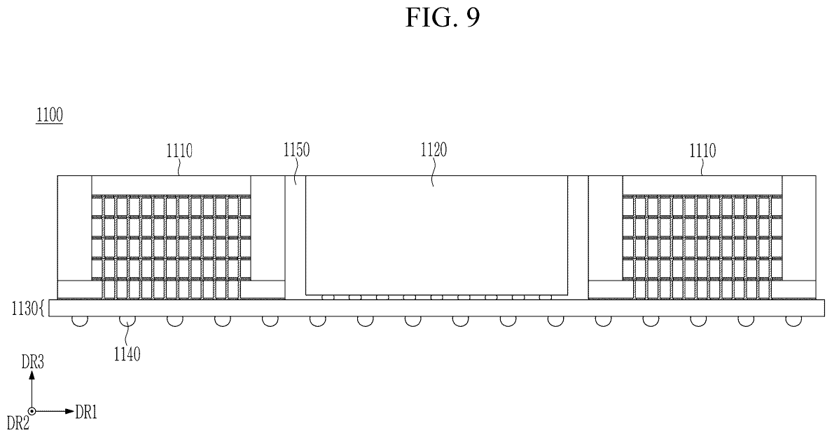

FIG. 9 is a cross-sectional view showing a 2.5D semiconductor package including a bonding structure according to some example embodiments.

A semiconductor package 1100 of FIG. 9 may include a plurality of first semiconductor chips 1110, a plurality of second semiconductor chips 1120, an interposer 1130, and a molding material 1150. The first semiconductor chips 1110 may include the semiconductor stacking structure, the lower die, and the molding material described with reference to FIG. 1. The second semiconductor chip 1120 may be a logic die.

A substrate (not shown) may be disposed below the interposer 1130. Connection members may be disposed on a lower surface of the interposer 1130. In some example embodiments, the interposer 1130 may include a silicon interposer.

The first semiconductor chips 1110 and the second semiconductor chip 1120 may be disposed on the interposer 1130. The first semiconductor chips 1110 and the second semiconductor chip 1120 may be bonded to the interposer 1130 by, for example hybrid bonding. The second semiconductor chip 1120 may include connection pads and an insulation layer for hybrid bonding. Regarding the hybrid bonding, the contents of hybrid bonding described with reference to FIG. 1 to FIG. 7 may be applied in the same way.

The second semiconductor chip 1120 may be disposed side-by-side with the first semiconductor chips 1110 between the first semiconductor chips 1110. In some example embodiments, the second semiconductor chip 1120 may include, for example, a system-on-chip (SoC) but example embodiments are not limited thereto. In some example embodiments, the second semiconductor chip 1120 may include, for example, a central processing unit (CPU) or a graphics processing unit (GPU), but example embodiments are not limited thereto.

A molding material 1150 may be disposed on the interposer 1130 and on the first semiconductor chips 1110 and may mold (for example, surround or at least partially surround) the second semiconductor chip 1120. The molding material 1150 may serve to protect and/or insulate the first semiconductor chips 1110 and the second semiconductor chip 1120. In some example embodiments, the molding material 1150 may be formed of a thermosetting resin such, for example, as epoxy resin, but example embodiments are not limited thereto. In some example embodiments, the molding material 1150 may be an epoxy molding compound (EMC). In some example embodiments, the process of molding with the molding material 1150 may include a compression molding and/or transfer molding process, but example embodiments are not limited thereto.

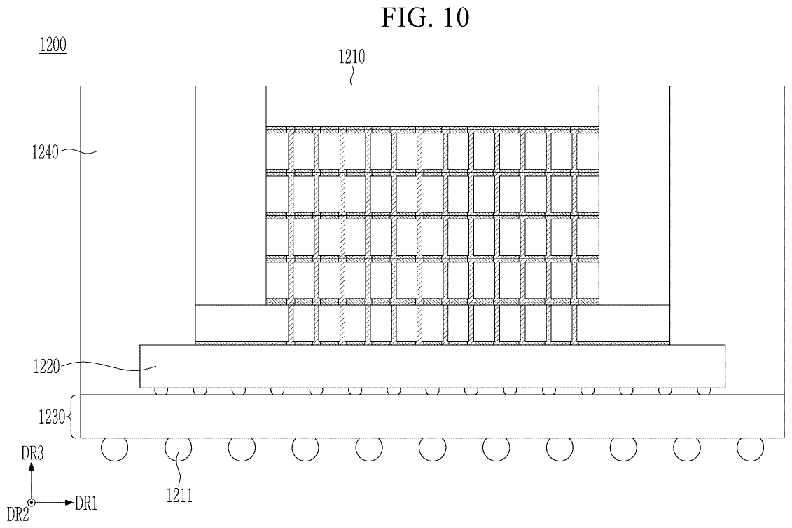

FIG. 10 is a cross-sectional view showing a 3D semiconductor package including a bonding structure according to some example embodiments.

A semiconductor package 1200 of FIG. 10 may include a first semiconductor chip 1210, a second semiconductor chip 1220, an interposer 1230, and a molding material 1240. The first semiconductor chip 1210 may include the semiconductor stacking structure, the lower die and the molding material described with reference to FIG. 1. The second semiconductor chip 1220 may be or include a logic die.

A substrate (not shown) may be disposed below the interposer 1230. Connection members may be disposed on a lower surface of the interposer 1230. In some example embodiments, the interposer 1230 may include a silicon interposer. The second semiconductor chip 1220 may be disposed on the interposer 1230. The second semiconductor chip 1220 may be bonded to the interposer 1230 by, for example, hybrid bonding. Regarding the hybrid bonding, the contents of hybrid bonding described with reference to FIG. 1 to FIG. 7 may be applied in the same way.

In some example embodiments, the second semiconductor chip 1220 may include a system-on-chip (SoC). In some example embodiments, the second semiconductor chip 1220 may include, for example, a central processing unit (CPU) or a graphics processing unit (GPU), but example embodiments are not limited thereto.

The first semiconductor chip 1210 may be disposed on the second semiconductor chip 1220. The first semiconductor chip 1210 may be bonded to the second semiconductor chip 1220 by hybrid bonding. Regarding the hybrid bonding, the contents of hybrid bonding described with reference to FIG. 1 to FIG. 9 may be applied in the same way.

The molding material 1240 may be disposed on the interposer 1230 on and the first semiconductor chip 1210, and may mold (for example, surround or at least partially surround) the second semiconductor chip 1220. The molding material 1240 may serve to protect and insulate the first semiconductor chip 1210 and the second semiconductor chip 1220. In some example embodiments, the molding material 1240 may be formed of or include a thermosetting resin such as epoxy resin, but example embodiments are not limited thereto. In some example embodiments, the molding material 1240 may be or include an epoxy molding compound (EMC). In some example embodiments, the process of molding with (for example, disposing) the molding material 1240 may include a compression molding or transfer molding process.

While inventive concepts have been described in connection with what are presently considered to be practical example embodiments, it is to be understood that inventive concepts are not limited to the mentioned example embodiments, but, on the contrary, are intended to cover various modifications and equivalent arrangements included within the spirit and scope of the appended claims as understood by one of ordinary skill in the art.

What is claimed is:

1. A semiconductor package, comprising:
a first semiconductor chip comprising
a first semiconductor layer;
an upper wire structure on the first semiconductor layer;
an upper connection pad on the upper wire structure; and
a first upper conductive pattern between the upper wire structure and the upper connection pad,
wherein the first upper conductive pattern comprises aluminum doped with a metallic material, the metallic material having a lower coefficient of thermal expansion than aluminum.

2. The semiconductor package of claim 1, wherein the first upper conductive pattern does not comprise silicon (Si).

3. The semiconductor package of claim 1, wherein the metallic material comprises at least one of copper (Cu), ruthenium (Ru), tungsten (W), or nickel (Ni).

4. The semiconductor package of claim 1, wherein
the first semiconductor chip further comprises a second upper conductive pattern, the second upper conductive pattern being between the upper wire structure and the upper connection pad; and
the second upper conductive pattern comprises aluminum doped with silicon.

5. The semiconductor package of claim 4, wherein the second upper conductive pattern is below the first upper conductive pattern, or the second upper conductive pattern is above the first upper conductive pattern.

6. The semiconductor package of claim 4, wherein a grain size of the aluminum comprised in the second upper conductive pattern is smaller than a grain size of the aluminum comprised in the first upper conductive pattern.

7. The semiconductor package of claim 1, wherein a thickness of the first upper conductive pattern is greater than or equal to 0.5 μm and smaller than or equal to 2.5 μm.

8. The semiconductor package of claim 1, further comprising:
a second semiconductor chip located on the first semiconductor chip,
wherein the first semiconductor chip further comprises an upper interface insulation layer located on the upper wire structure and at least partially surrounding a side surface of the upper connection pad;
the second semiconductor chip further comprises a second semiconductor layer, a lower connection pad located below the second semiconductor layer, and a lower interface insulation layer surrounding a side surface of the lower connection pad, and
an upper surface of the upper connection pad and an upper surface of the upper interface insulation layer are in contact with a lower surface of the lower connection pad and a lower surface of the lower interface insulation layer, respectively.

9. The semiconductor package of claim 8, wherein the upper connection pad and the lower connection pad comprise a same metallic material, and the upper interface insulation layer and the lower interface insulation layer comprise a same insulating material.

10. The semiconductor package of claim 1, wherein the first semiconductor chip further comprises:
a second upper conductive pattern between the upper wire structure and the upper connection pad, and below the first upper conductive pattern; and
a third upper conductive pattern between the first upper conductive pattern and the second upper conductive pattern,
wherein the second upper conductive pattern comprises aluminum doped with silicon, and
the third upper conductive pattern does not comprise silicon.

11. The semiconductor package of claim 1, wherein the first semiconductor chip further comprises:
a first barrier pattern on a lower surface of the first upper conductive pattern; and
a second barrier pattern on an upper surface of the first upper conductive pattern.

12. The semiconductor package of claim 11, wherein the first barrier pattern comprises titanium (Ti), and the second barrier pattern comprises titanium nitride (TiN).

13. A semiconductor package, comprising:
a first semiconductor chip comprising
a first semiconductor layer;
an upper wire structure on the first semiconductor layer;
an upper connection pad on the upper wire structure; and
first upper conductive pattern and a second upper conductive pattern between the upper wire structure and the upper connection pad,
wherein the first upper conductive pattern comprises aluminum that is not doped with silicon, and
the second upper conductive pattern comprises aluminum doped with silicon.

14. The semiconductor package of claim 13, wherein the first upper conductive pattern comprises aluminum doped with a metallic material, the metallic material having a lower coefficient of thermal expansion than aluminum.

15. The semiconductor package of claim 14, wherein the metallic material comprises at least one of aluminum (Al), copper (Cu), ruthenium (Ru), tungsten (W), or nickel (Ni).

16. The semiconductor package of claim 13, wherein a grain size of the aluminum comprised in the second upper conductive pattern is smaller than a grain size of the aluminum comprised in the first upper conductive pattern.

17. The semiconductor package of claim 13, further comprising:
a second semiconductor chip located on the first semiconductor chip;
wherein the first semiconductor chip further comprises an upper interface insulation layer on the upper wire structure and at least partially surrounding a side surface of the upper connection pad, and
the second semiconductor chip further comprises a second semiconductor layer, a lower connection pad below the second semiconductor layer, and a lower interface insulation layer at least partially surrounding a side surface of the lower connection pad, and
an upper surface of the upper connection pad and an upper surface of the upper interface insulation layer are in contact with a lower surface of the lower connection pad and a lower surface of the lower interface insulation layer, respectively.

18. The semiconductor package of claim 17, wherein the upper connection pad and the lower connection pad comprise a same metallic material, and the upper interface insulation layer and the lower interface insulation layer comprise a same insulating material.

19. A semiconductor package, comprising:
an interposer;
a logic die on the interposer; and
a high bandwidth memory on the interposer,
wherein the high bandwidth memory comprises a first semiconductor chip and a second semiconductor chip, the second semiconductor chip connected to the first semiconductor chip,
the first semiconductor chip comprises
a first semiconductor layer;
an upper wire structure on the first semiconductor layer;
an upper connection pad on the upper wire structure; and
a first upper conductive pattern between the upper wire structure and the upper connection pad, and
the first upper conductive pattern comprises aluminum doped with a metallic material, the metallic material having a lower coefficient of thermal expansion than aluminum.

20. The semiconductor package of claim 19, wherein
the first semiconductor chip further comprises a second upper conductive pattern, the second upper conductive pattern located between the upper wire structure and the upper connection pad; and
the second upper conductive pattern comprises aluminum doped with silicon.
